(19) United States
(12) Patent Application Publication
(10) Pub. No.: US 2008/0150545 A1
(43) Pub. Date: Jun. 26, 2008

(54) COMPUTER CONNECTOR TESTER

(75) Inventors: KE SUN, Shenzhen (CN); MING-KE CHEN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/736,010

(22) Filed: Apr. 17, 2007

(30) Foreign Application Priority Data
Dec. 22, 2006 (CN) 200610201365.6

(51) Int. Cl. H05K 13/00

(52) U.S. Cl. 324/537

(57) ABSTRACT

A connector tester for testing connectors of a control panel of a computer includes a micro control unit (MCU), at least one first test channel, at least one second test channel, a control circuit, and a display circuit. The two at least one test channels receive a select signal from the MCU for forming a test loop with the connectors that are connected to the two or more test channels. The control circuit controls the MCU to transmit the select signal to the two or more test channels. The display circuit is controlled by the MCU to display test result of the connectors, if the test loop is electrically closed, the MCU controls the display circuit to show a good test result for the connectors; if the test loop is electrically open, the MCU controls the display circuit to show a bad test result for the connectors.

### BACKGROUND OF THE INVENTION

1. Field of the Invention

The present invention relates to computer connector testers, and particularly to a computer connector tester which can test connectors of different kinds that are installed on a control panel of a computer.

2. Description of Related Art

Generally speaking, most computers and servers have many kinds of connectors, such as USB connectors, arranged on control panels thereof. In manufacturing, the connectors are respectively tested by corresponding testers. Using these testers will prolong test time and increase test cost.

What is desired, therefore, is to provide a single computer connector tester which can test many kinds of connectors that are installed on a control panel of a computer at the same time.

### SUMMARY OF THE INVENTION

An exemplary connector tester for testing connectors of a control panel of a computer includes a micro control unit (MCU), at least one first test channel, at least one second test channel, a control circuit, and a display circuit. The two or more test channels receive a select signal from the MCU for forming a test loop with the connectors that are connected to the two or more test channels. The control circuit controls the MCU to transmit the select signal to the two at least one test channels. The display circuit is controlled by the MCU to display test result of the connectors, if the test loop is electrically closed, the MCU controls the display circuit to show a good test result for the connectors; if the test loop is electrically open, the MCU controls the display circuit to show a bad test result for the connectors.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is an exploded, isometric view of a computer connector tester in accordance with a preferred embodiment of the present invention;

FIG. 2 is an assembled view of FIG. 1; and

FIG. 3 is a circuit diagram of the computer connector tester of FIG. 1.

### DETAILED DESCRIPTION OF THE INVENTION

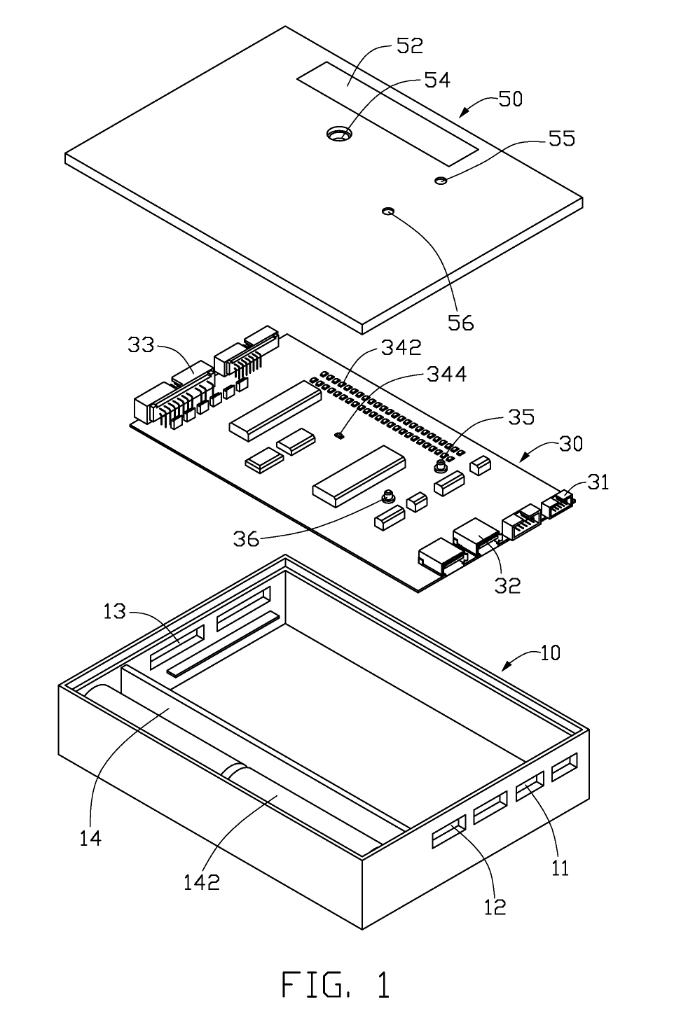

Referring to FIG. 1, a computer connector tester in accordance with a preferred embodiment of the present invention is provided for testing connectors mounted on a control panel of a computer. The computer connector tester includes a case 10, a printed circuit board (PCB) 30 arranged in the case 10, and a cover 50 for covering the case 10.

Two first through holes 11 and two second through holes 12 are defined in one side wall of the case 10, and two third through holes 13 are defined in an opposite side wall of the case 10. A battery compartment 14 is defined in the case 10 for installation of batteries 142 therein, to supply power to the computer connector tester.

Two first connectors 31 and two second connectors 32 are arranged on one end of the PCB 30, and two third connectors 33 are arranged on an opposite end of the PCB 30. The connectors 31, 32, 33 respectively correspond to the through holes 11, 12, 13 of the case 10. The PCB 30 includes a plurality of two-way light-emitting diodes (LEDs) 342, an LED 344, a first switch 35, and a second switch 36 arranged thereon. In this embodiment, one of the first connectors 31 includes 10 pins (each pin is 2.00 mm) in a 2*5 pattern, and the other one of the first connectors 31 includes 10 pins (each pin is 2.54 mm) in a 2*5 pattern. Each of the second connectors 32 is a universal serial bus (USB) connector (includes 5 pins). One of the third connectors 33 includes 24 pins (each pin is 2.00 mm) 2*12 pattern, and the other one of the third connectors 33 includes 24 pins (each pin is 2.54 mm) 2*12 pattern. In other embodiments, the connectors 31, 32, 33 can also be changed to any kinds of electrically connectors (includes male and female connectors) according to actual need. An amount of the two-way LEDs 342 is 48, and the two-way LEDs 342 are arranged in a 2×24 matrix on the PCB 30. Other numbers and arrangements of two-way LEDs 342 can also be utilized to practice the present invention according to need.

The cover 50 includes a window 52 corresponding to the two-way LEDs 342. Three through holes 54, 55, 56 are defined in the cover 50 respectively corresponding to the LED 344, the first switch 35, and the second switch 36.

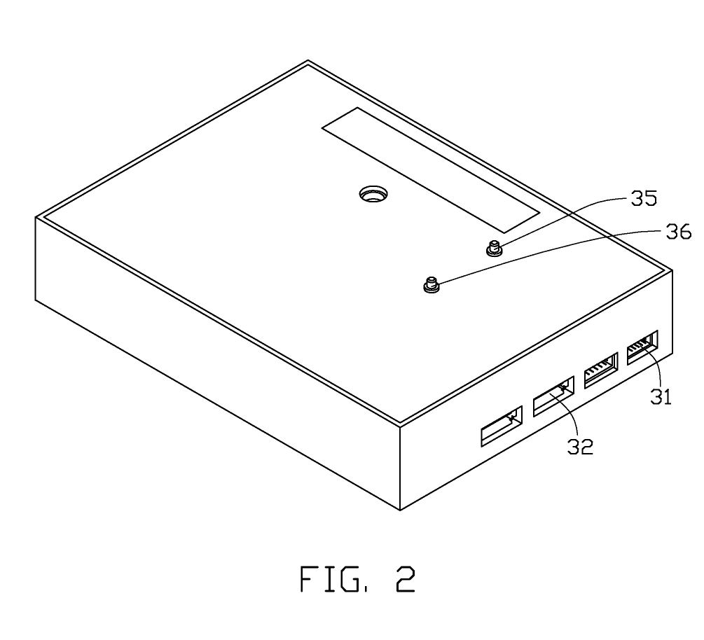

Referring also to FIG. 2, in assembly, the PCB 30 is installed in the case 10. The connectors 31, 32, 33 are respectively exposed via the through holes 11, 12, and 13. The two-way LEDs 342 can be viewed via the window 52. The LED 344, the first switch 35, and the second switch 36 are exposed to external view via the three though holes 54, 55, 56, respectively.

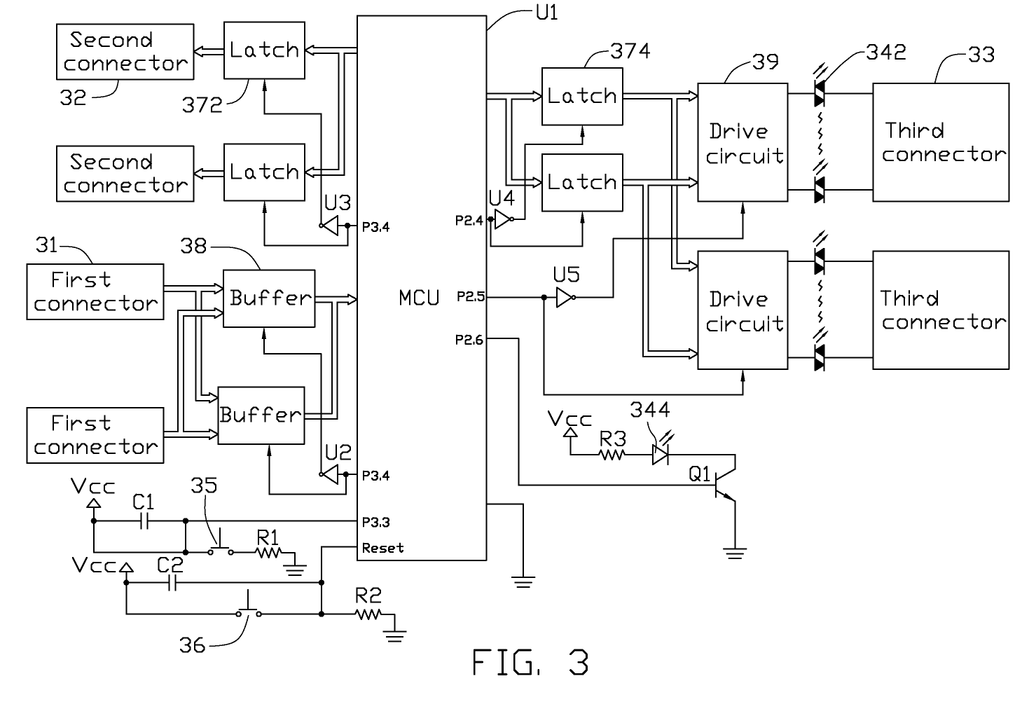

Referring also to FIG. 3, a test circuit arranged in the PCB 30 includes a micro control unit (MCU) U1, two 4-bit latches 372 corresponding to the second connectors 32, two 12-bit latches 374 corresponding to the third connectors 33, two 4-bit buffers 38 corresponding to the first connectors 31, two drive circuits 39 for amplifying current, two capacitors C1 and C2, and three resistors R1, R2, and R3.

Each first connectors 31 transmit data to the MCU U1 via the buffers 38. An I/O pin P3.4 of the MCU U1 is connected to one of the buffers 38, and is also connected to the other one of the buffers 38 via a not gate U2. Each first connector 31 and the two buffers 38 form two first test channels, namely, a group first test channels. The MCU U1 selects one of the group first test channels via the I/O pin P3.4.

The MCU U1 transmits data to the second connectors 32 via the corresponding latches 372. Each latch 372 and its corresponding second connector 32 form a second test channel. An input/output (I/O) pin P3.4 of the MCU U1 is connected to one of the latches 372, and is also connected to the other one of the latches 372 via a not gate U3. The MCU U1 selects one of the two second test channels via the I/O pin P3.4. The first test channels correspond to the second test channels respectively.

The MCU U1 transmits data to the drive circuits 39 via the corresponding latches 374. Each of the drive circuits 39 is connected to and drives one line of the two-way LEDs 342, and one line of the two-way LEDs 342 is correspondingly connected to one of the third connectors 33. Each of the latches 374, its corresponding drive circuit 39, and corresponding one line of the two-way LEDs 342 form a third test channel. An I/O pin P2.4 is connected to one of the latches 374, and also connected to the other one of the latches 374 via a not gate U4. An I/O pin P2.5 is connected to one of the drive circuits 39, and is also connected to the other one of the drive circuits 39 via a not gate U5. The MCU U1 selects one of the two third test channels via the I/O pin P2.4 and I/O pin P2.5.

An I/O pin P2.6 is connected to a base of a transistor Q1, a collector of the transistor Q1 is connected to a cathode of the LED 344. An anode of the LED 344 is connected to a power supply source Vcc via the resistor R3. The power supply source Vcc is the batteries 142 installed in the battery compartment 14. An emitter of the transistor Q1 is grounded. The transistor Q1, LED 344, and resistor R3 compose a display circuit for showing test results of the second test channel and its corresponding first test channel.

An I/O pin P3.3 of the MCU U1 is connected to the power supply source Vcc, and also connected to the power supply source Vcc via the capacitor C1, and also connected to ground via the first switch 35 and the resistor R1 in turn. The capacitor C1, first switch 35, and resistor R1 compose a control circuit for controlling the first and second test channels.

A reset pin Reset is connected to ground via the resistor R2, and also connected to the power supply source Vcc via the capacitor C2, and is also connected to the power supply source Vcc via the second switch 36. The capacitor C2, second switch 36, and resistor R2 compose a reset circuit for resetting the MCU U1.

Before testing the connectors mounted on the control panel of the computer, the MCU U1 is programmed according to need. The connectors mounted on the control panel of the computer are connected to the corresponding first, second, and third connectors 31, 32, 33 of the computer connector tester via corresponding data cables (not shown). In this embodiment, the connectors mounted on the control panel includes two USB connectors corresponding to the second connectors 32, a connector which includes 10 pins in a 2*5 pattern corresponding to one of the first connectors 31, and a connector which includes 24 pins in a 2*12 pattern corresponding to one of the third connectors 33. The I/O pin P3.4 of the MCU U1 transmits a select signal according to the program of the MCU U1. The select signal includes a first select signal and a second select signal, and the two select signal swap each other at a certain frequency. The first select signal selects one of the second test channels and its corresponding first test channel consisting of the one of the first connectors 31 and one of the buffers 38, so that the selected second test channel, the connector mounted on the control panel corresponding to the selected second test channel, the computer, the connector mounted on the control panel corresponding to the first test channel, and the first test channel form a test loop. The second select signal selects the other one of the second test channels and its corresponding first test channel consisting of the one of the first connectors 31 and the other one of the buffers 38, so that the selected second test channel, the connector mounted on the control panel corresponding to the selected second test channel, the computer, the connector mounted on the control panel corresponding to the first test channel, and the first test channel form a test loop. Then, the first switch 35 is pressed, a voltage level of the I/O pin P3.3 is goes from high to low. If the tested connectors mounted on the control panel are good, the I/O pin P2.6 outputs a high voltage signal to turn on the LED 344. If the tested connectors are bad, the I/O pin P2.6 outputs a low voltage signal, and the LED 344 will not be turned on.

The I/O pin P2.5 and I/O pin P2.6 of the MCU U1 both transmit a select signal according to the program of the MCU U1. The select signal selects one of the third test channels, if the corresponding tested connector is good, the corresponding drive circuit 39 drives the corresponding line of the two-way LEDs 342 turn on. If the corresponding tested connector is bad, the corresponding drive circuit 39 will not drive the corresponding line of the two-way LEDs 342.

Before testing connectors of a control panel of another computer, the second switch 36 is pressed to reset the MCU U1. Then the connectors of another computer can be tested in the aforesaid method. Because the MCU U1 can be programmed according to need, the computer connector tester can test many kinds of connectors of control panels of computers, it may save test time and reduce test cost.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A connector tester for testing connectors mounted on a control panel of a computer, comprising:
a micro control unit (MCU);
at least one first test channel;
at least one second test channel connecting to the at least one first test channel via the MCU, the at least one first test channel and the at least one second test channel receiving a select signal from the MCU for forming a test loop with the connectors to be tested that are connected to the at least one first test channel and the at least one second test channel;
a control circuit controlling the MCU to transmit the select signal to the at least one first test channel and the at least one second test channel; and
a display circuit controlled by the MCU to display test result of the tested connectors, wherein if the test loop is electrically closed, the MCU controls the display circuit to show a good test result for the tested connectors, if the test loop is electrically open, the MCU controls the display circuit to show a bad test result for the tested connectors.

2. The connector tester as claimed in claim 1, wherein the at least one first test channel comprises two groups of first test channels each comprising two first test channels, the at least one second test channel comprises two second test channels corresponding to the two first test channels of one of the two groups of first test channels respectively, an I/O pin of the MCU transmits the select signal to select one of the first test channels and its corresponding second test channel.

3. The connector tester as claimed in claim 2, wherein the two groups of first test channels comprises two first connectors configured for connecting with some of the tested connectors, and two buffers each connecting the two first connectors with the MCU for transmitting data from the first connectors to the MCU and receiving the select signal from the MCU, each first connector and any one of the buffers cooperatively forming one of the first test channels, the I/O pin connecting with one of the buffers via a NOT gate and connecting with the other one of the buffers directly.

4. The connector tester as claimed in claim 2, wherein each of the second test channels comprises a latch for receiving data and the select signal from the MCU, and a second connector connected to the latch configured for connecting with one of the tested connectors, the I/O pin connecting with one of the latches via a NOT gate and connecting with the other one of the latches directly.

5. The connector tester as claimed in claim 1, further comprising at least one third test channel controlled by the MCU to test one of the connectors to be tested of the control panel.

6. The connector tester as claimed in claim 5, wherein the at least one third test channel comprises a latch for receiving data and the select signal from the MCU, a drive circuit for amplifying the data received by the latch, a plurality of two-way light-emitting diodes (LEDs) driven by the drive circuit for showing test result of the at least one third test channel, and at least one third connector electrically coupled to the two-way LEDs, wherein the at least one third connector is configured for connecting with said one of the connectors to be tested of the control panel.

7. The connector tester as claimed in claim 1, wherein the control circuit comprises a capacitor, a first switch, and a resistor, an I/O pin of the MCU is connected to a power supply source, and also connected to the power supply source via the capacitor, and also connected to ground via the first switch and the resistor in turn.

8. The connector tester as claimed in claim 1, further comprising a reset circuit for resetting the MCU.

9. The connector tester as claimed in claim 8, wherein the reset circuit comprises a capacitor, a second switch, and a resistor, a reset pin of the MCU is connected to ground via the resistor, and also connected to a power supply source via the capacitor, and also connected to the power supply source via the second switch.

10. The connector tester as claimed in claim 1, wherein the display circuit comprises a transistor, an LED, and a resistor, an I/O pin of the MCU is connected to a base of a transistor, a collector of the transistor is connected to a cathode of the LED, an anode of the LED is connected to a power supply source via the resistor, an emitter of the transistor is grounded.

11. A connector test method for testing connectors mounted on a control panel of a computer via a connector tester which comprises a micro control unit (MCU), at least one first test channel, at least one second test channel corresponding to the at least one first test channel, a control circuit, and a display circuit, comprising:
connecting the at least one first test channel, the connectors mounted on the control panel, and the at least one second test channel to form a test loop;
the control circuit controlling the MCU to transmit a select signal to the at least one first test channel and the at least one second test channel; and
the display circuit controlled by the MCU to display test result of the connectors, wherein if the test loop is electrically closed, the MCU controls the display circuit to show a good test result for the connectors, if the test loop is electrically open, the MCU controls the display circuit to show a bad test result for the connectors.

12. The connector test method as claimed in claim 11, wherein the at least one first test channel comprises two groups of first test channels, each comprising two first test channels, the at least one second test channel comprises two second test channels corresponding to the two first test channels of one of the two groups first test channel respectively, an I/O pin of the MCU transmits the select signal to select one of the first test channels and its corresponding second test channel.

13. The connector test method as claimed in claim 11, wherein the tester further comprises at least one third test channel controlled by the MCU to test other connectors mounted on the control panel.

14. The connector test method as claimed in claim 13, wherein the at least one third test channel comprises a latch for receiving data and a select signal from the MCU, a drive circuit for amplifying the data received by the latch, a plurality of two-way light-emitting diodes (LEDs) drove by the drive circuit for showing test result of the at least one third test channel, and at least one third connector electrically coupled to the two-way LEDs, wherein the at least one third connector is adapted for connecting with the other connectors mounted on the control panel.

15. The connector test method as claimed in claim 11, wherein the control circuit comprises a capacitor, a first switch, and a resistor, an I/O pin of the MCU is connected to a power supply source, and also connected to the power supply source via the capacitor, and also connected to ground via the first switch and the resistor in turn.

16. The connector test method as claimed in claim 11, further comprising: providing a reset circuit for resetting the MCU.

17. The connector test method as claimed in claim 16, wherein the reset circuit comprises a capacitor, a second switch, and a resistor, a reset pin of the MCU is connected to ground via the resistor, and also connected to a power supply source via the capacitor, and also connected to the power supply source via the second switch.

18. The connector test method as claimed in claim 11, wherein the display circuit comprises a transistor, a LED, and a resistor, an I/O pin of the MCU is connected to a base of a transistor, a collector of the transistor is connected to a cathode of the LED, an anode of the LED is connected to a power supply source via the resistor, an emitter of the transistor is grounded.

19. A connector tester for testing connectors of a computer, comprising:
a micro control unit (MCU);
a plurality of first test channels connecting with the MCU;
a plurality of second test channels connecting with the MCU;
a control circuit controlling the MCU to transmit a select signal to select one of the first test channels and a corresponding one of the second test channels to cooperatively form a test loop with the connectors of the computer that are connected to the selected one of the first test channels and the selected one of the second test channel; and
a display circuit controlled by the MCU to display test result of the tested connectors, wherein if the test loop is electrically closed, the MCU controls the display circuit to show a good test result for the tested connectors, if test loop is electrically open, the MCU controls the display circuit to show a bad test result for the tested connectors.

20. The connector tester as claimed in claim 19, comprising a plurality of first connectors configured to connect with the connectors of the computer, and a plurality of buffers each connecting all of the first connectors with the MCU, wherein each of the first connectors and any one of the buffers cooperatively forming one of the first test channels, and each of the second test channels comprises a second connector configured to connect with another one of the connectors of the computer, and a latch connecting the second connector with the MCU, the MCU comprising an I/O pin connecting with the latches and the buffers for transmitting the select signal thereto to select said one of the first test channels and the corresponding second test channel.

21. The connector tester as claimed in claim 20, wherein the first connectors of the first test channels have different structure, and the second connectors of the second test channels are USB connectors.
